(19) United States
(12) Patent Application Publication
(10) Pub. No.: US 2024/0324288 A1
(43) Pub. Date: Sep. 26, 2024

(54) DISPLAY APPARATUS

(71) Applicant: Samsung Display Co., Ltd., Yongin-si (KR)

(72) Inventors: Sunhwa Lee, Yongin-si (KR); Junhyun Park, Yongin-si (KR); Hyeongseok Kim, Yongin-si (KR); Heejean Park, Yongin-si (KR); Hanbit Kim, Yongin-si (KR)

(73) Assignee: Samsung Display Co., Ltd., Yongin-si (KR)

(21) Appl. No.: 18/583,109

(22) Filed: Feb. 21, 2024

(30) Foreign Application Priority Data
Mar. 24, 2023 (KR) 10-2023-0039064
Aug. 29, 2023 (KR) 10-2023-0113734

(51) Int. Cl. H10K 59/121; H10K 59/124; H10K 59/131

(52) U.S. Cl. CPC H10K 59/1213; H10K 59/1216; H10K 59/131; H10K 59/124

(57) ABSTRACT

A display apparatus includes a first thin-film transistor in a display area, and including a first semiconductor layer and a first gate electrode, the first semiconductor layer including a silicon semiconductor, a second thin-film transistor on the first thin-film transistor, and including a second semiconductor layer and a second gate electrode, the second semiconductor layer including an oxide semiconductor, a third thin-film transistor on the first thin-film transistor, and including a third semiconductor layer and a third gate electrode, the third semiconductor layer including an oxide semiconductor, a bridge metal layer between the first thin-film transistor and the second thin-film transistor and electrically connected to the first semiconductor layer through a first contact hole, and a first conductive pattern layer on the second gate electrode of the second thin-film transistor, and the bridge metal layer is electrically connected to the first conductive pattern layer through a second contact hole.

### CROSS-REFERENCE TO RELATED APPLICATION(S)

This application claims priority to and benefits of Korean Patent Application Nos. 10-2023-0039064 and 10-2023-0113734 under 35 U.S.C. § 119, filed respectively, on Mar. 24, 2023 and Aug. 29, 2023, in the Korean Intellectual Property Office, the entire contents of which are incorporated herein by reference.

### BACKGROUND

### 1. Technical Field

One or more embodiments relate to a display apparatus.

### 2. Description of the Related Art

Display apparatuses visually display data. Display apparatuses may provide images by using light-emitting diodes. Display apparatuses have been used for various purposes, and various designs have been attempted to improve the quality of display apparatuses.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus.

Additional aspects will be set forth in part in the description which follows and, in part, will be apparent from the description, or may be learned by practice of the presented embodiments.

According to one or more embodiments, a display apparatus may include a display area including a display element; a first thin-film transistor disposed in the display area, the first thin-film transistor including a first semiconductor layer and a first gate electrode insulated from the first semiconductor layer, the first semiconductor layer including a silicon semiconductor; a second thin-film transistor disposed on the first thin-film transistor, the second thin-film transistor including a second semiconductor layer and a second gate electrode insulated from the second semiconductor layer, the second semiconductor layer including an oxide semiconductor; a third thin-film transistor disposed on the first thin-film transistor, the third thin-film transistor including a third semiconductor layer and a third gate electrode insulated from the third semiconductor layer, the third semiconductor layer including an oxide semiconductor; a bridge metal layer disposed between the first thin-film transistor and the second thin-film transistor and electrically connected to the first semiconductor layer through a first contact hole; and a first conductive pattern layer disposed on the second gate electrode of the second thin-film transistor, wherein the bridge metal layer is electrically connected to the first conductive pattern layer through a second contact hole.

The second semiconductor layer may include a first portion extending in a first direction and a second portion protruding from the first portion in a second direction intersecting the first direction.

The second portion of the second semiconductor layer may be disposed between the second gate electrode of the second thin-film transistor and the third gate electrode of the third thin-film transistor in a plan view.

The first semiconductor layer may include a channel region, and a source region and a drain region disposed on both sides of the channel region, wherein the bridge metal layer is electrically connected to the source region and the drain region of the first semiconductor layer through the first contact hole.

The second semiconductor layer and the third semiconductor layer may be disposed on a same layer and include a same material, and the second gate electrode and the third gate electrode may be disposed on a same layer and include a same material.

The first thin-film transistor may include a driving transistor, and each of the second thin-film transistor and the third thin-film transistor may include a switching transistor.

The first conductive pattern layer may include a driving voltage line.

The display apparatus may further include a first scan line and a second scan line disposed below the second semiconductor layer to overlap at least a part of the second semiconductor layer, and extending in a first direction.

The first scan line, the second scan line, and the bridge metal layer may be disposed on a same layer and include a same material.

The display apparatus may further include a first capacitor including a first lower electrode disposed on the first semiconductor layer and a first upper electrode disposed on the first lower electrode.

The first lower electrode and the first gate electrode of the first thin-film transistor may be integral with each other.

The display apparatus may further include a second capacitor including a second lower electrode disposed on the second thin-film transistor and a second upper electrode disposed on the second lower electrode.

The second lower electrode and at least a part of the first conductive pattern layer may be integral with each other.

The display apparatus may further include a second conductive pattern layer disposed on the first conductive pattern layer, and a third conductive pattern layer disposed between the first conductive pattern layer and the second conductive pattern layer.

The first conductive pattern layer may be electrically connected to at least a part of the second conductive pattern layer through a third contact hole.

The display apparatus may further include a third storage capacitor including a third lower electrode disposed on the second thin-film transistor, a third upper electrode disposed on the third lower electrode, and a third intermediate electrode disposed between the third upper electrode and the third lower electrode.

The third lower electrode may be integral with at least a part of the first conductive pattern layer, the third upper electrode may be integral with at least a part of the second conductive pattern layer, and the third intermediate electrode may be integral with at least a part of the third conductive pattern layer.

According to one or more embodiments, a display apparatus may include a display area including a display element;
a first thin-film transistor disposed in the display area, the first thin-film transistor including a first semiconductor layer and a first gate electrode insulated from the first semiconductor layer, the first semiconductor layer including a silicon semiconductor;
a second thin-film transistor disposed in the display area, the second thin-film transistor including a second semiconductor layer and a second gate electrode insulated from the second semiconductor layer, the second semiconductor layer including a silicon semiconductor;
a third thin-film transistor disposed on the first thin-film transistor, the third thin-film transistor including a third semiconductor layer and a third gate electrode insulated from the third semiconductor layer, the third semiconductor layer including an oxide semiconductor; an initialization voltage line disposed on the first gate electrode and the second gate electrode; and a bridge metal layer disposed between the initialization voltage line and the third thin-film transistor, and electrically connected to the initialization voltage line through a first contact hole, wherein the bridge metal layer is electrically connected to the second gate electrode of the second thin-film transistor through a second contact hole.

The first semiconductor layer of the first thin-film transistor and the second semiconductor layer of the second thin-film transistor may be disposed on a same layer and may include a same material, and the first gate electrode and the second gate electrode may be disposed on a same layer and may include a same material.

The first thin-film transistor may include a driving transistor, and each of the second thin-film transistor and the third thin-film transistor may include a switching transistor.

### BRIEF DESCRIPTION OF THE DRAWINGS

The above and other aspects, features, and advantages of embodiments will be more apparent from the following description taken in conjunction with the accompanying drawings, in which:

FIG. 1 is a view schematically illustrating a display apparatus, according to embodiments;

FIG. 2 is a schematic diagram of an equivalent circuit illustrating a pixel circuit for driving a pixel and an organic light-emitting diode as a display element connected to the pixel circuit, according to an embodiment;

FIG. 3 is a schematic plan view schematically illustrating positions of thin-film transistors and capacitors located in a pair of pixel circuits of a display apparatus, according to an embodiment;

FIG. 4 is a schematic cross-sectional view taken along line I-I′ of FIG. 3;

FIG. 5 is a schematic cross-sectional view taken along line II-II′ of FIG. 3;

FIGS. 6A to 6H are schematic plan views schematically illustrating devices of FIG. 3 according to layers;

FIG. 7 is a schematic plan view schematically illustrating positions of thin-film transistors and capacitors located in a pair of pixel circuits of a display apparatus, according to an embodiment;

FIG. 8 is a schematic cross-sectional view taken along line III-III′ of FIG. 7; FIG. 9 is a schematic cross-sectional view taken along line IV-IV′ of FIG. 7;

FIGS. 10A to 10C are schematic plan views schematically illustrating at least some or a number of devices of FIG. 7 according to layers;

FIG. 11 is a schematic plan view schematically illustrating positions of thin-film transistors and capacitors located in a pair of pixel circuits of a display apparatus, according to an embodiment;

FIG. 12 is a schematic diagram of an equivalent circuit schematically illustrating a pixel of an embodiment of FIG. 11;

FIG. 13 is a schematic cross-sectional view taken along line V-V′ of FIG. 11; and

FIGS. 14A to 14F are views schematically illustrating devices of FIG. 11 according to layers.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof may be omitted.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms “a,” “an,” and “the” are intended to include the plural forms as well, unless the context clearly indicates otherwise.

It will be understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that, when a layer, region, or component is referred to as being “on” another layer, region, or component, it may be directly on the other layer, region, or component, or may be indirectly on the other layer, region, or component with intervening layers, regions, or components therebetween.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Sizes of components in the drawings may be exaggerated or reduced for convenience of explanation. For example, because sizes and thicknesses of elements in the drawings may be arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order opposite to the described order.

“A and/or B” is used herein to select only A, select only B, or select both A and B. “At least one of A and B” is used to select only A, select only B, or select both A and B.

It will be understood that when a layer, a region, or a component is referred to as being “connected” to another layer, region, or component, it may be “directly connected” to the other layer, region, or component and/or may be “indirectly connected” to the other layer, region, or component with other layers, regions, or components interposed therebetween. For example, when a layer, a region, or a component is referred to as being “electrically connected,” it may be directly electrically connected, and/or may be indirectly electrically connected with intervening layers, regions, or components therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

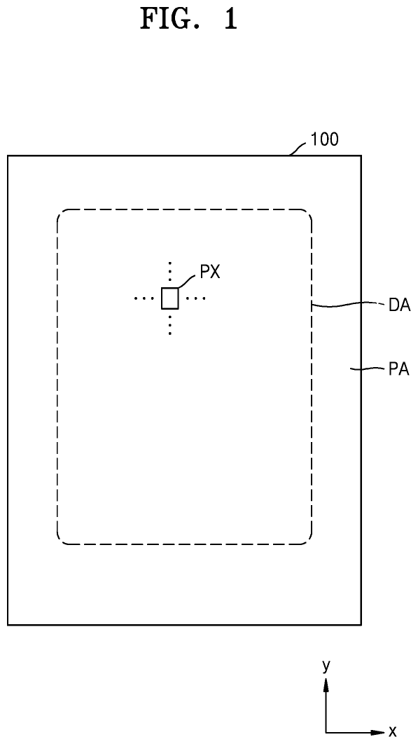

FIG. 1 is a view schematically illustrating a display apparatus, according to embodiments.

A display apparatus according to embodiments may be implemented as an electronic device such as a smartphone, a mobile phone, a navigation device, a game console, a TV, a vehicle head unit, a notebook computer, a laptop computer, a tablet computer, a personal media player (PMP), or a personal digital assistant (PDA). Also, the electronic device may be a flexible device.

A substrate 100 may be divided into a display area DA where an image is displayed and a peripheral area PA located (or disposed) around the display area DA.

The substrate 100 may include any of various materials, for example, glass, metal, or plastic. According to an embodiment, the substrate 100 may include a flexible material. The flexible material refers to a substrate that is well bendable, foldable, or rollable. The substrate 100 including the flexible material may be formed of ultra-thin glass, metal, or plastic.

Pixels PX including various display elements such as an organic light-emitting diode (OLED) may be located in the display area DA of the substrate 100. Pixels PX may be provided, and the pixels PX may be arranged or disposed in any of various types such as a stripe type, a PENTILE™ type, or a mosaic type to form an image.

In a plan view, the display area DA may have a rectangular shape as shown in FIG. 1.

In an embodiment, the display area DA may have a polygonal shape (for example, a triangular shape, a pentagonal shape, or a hexagonal shape), a circular shape, an elliptical shape, or an irregular shape. It is to be understood that the shapes disclosed herein may include shapes that are substantial to the shapes disclosed herein.

The peripheral area PA of the substrate 100 located around the display area DA may be an area where an image is not displayed. Various wirings for transmitting electric signals to be applied to the display area DA, and pads to which a printed circuit board or a driver integrated circuit (IC) chip is attached may be located in the peripheral area PA.

Hereinafter, a display apparatus including an organic light-emitting diode as a display element will be described for convenience of explanation. However, embodiments may be applied to various types of display apparatuses such as a liquid crystal display apparatus, an electrophoretic display apparatus, and an inorganic electroluminescent (EL) display apparatus.

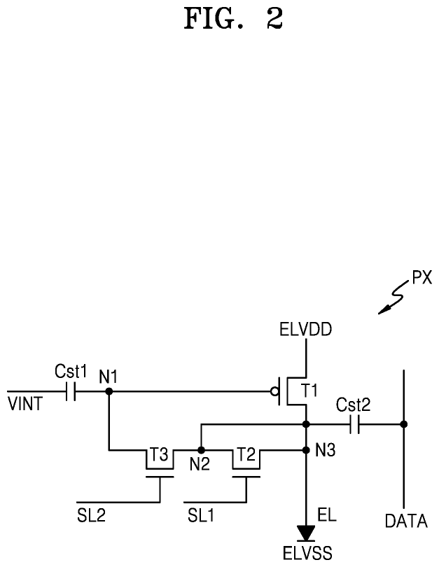

FIG. 2 is a schematic diagram of an equivalent circuit illustrating a pixel circuit for driving a pixel and an organic light-emitting display diode as a display element connected to the pixel circuit, according to an embodiment.

The display apparatus according to an embodiment has a 3-Transistor-2-capacitor (3T2C) structure including one driving transistor (for example, T1), two switching transistors (for example, T2 and T3), and two capacitors (for example, Cst1 and Cst2).

A driving transistor T1 may be located between a driving voltage line ELVDD and a third node N3, a second switching transistor T3 may be located between a first node N1 and a second node N2, and a first switching transistor T2 may be located between the second node N2 and the third node N3.

The first switching transistor T2 is turned on by a scan signal of a first scan line to connect the second node N2 to the third node N3. A gate electrode of the first switching transistor T2 may be connected to the first scan line, a first electrode may be connected to the third node N3, and a second electrode may be connected to the second node N2.

In case that both the first switching transistor T2 and the second switching transistor T3 are turned on, because a second electrode and a gate electrode of the driving transistor T1 are connected to each other, the driving transistor T1 operates as a diode.

The first node N1 may be a contact point among the gate electrode of the driving transistor T1, a first lower electrode of the first capacitor Cst1, and a second electrode of the second switching transistor T3. The second node N2 may be a contact point among the second electrode of the first switching transistor T2, a first electrode of the second switching transistor T3, and a second lower electrode of the second capacitor Cst2. The third node N3 may be a contact point among the second electrode of the driving transistor T1, the first electrode of the first switching transistor T2, and a first electrode of a light-emitting device EL.

In an embodiment, each pixel PX may include the first switching transistor T2 located between the second node N2 and the third node N3. Accordingly, because the second node N2 and the third node N3 may be separated from each other by the first switching transistor T2, even in case that leakage current flowing from the driving voltage line ELVDD to the third node N3 through the driving transistor T1 is generated while a data voltage of a data line DATA is applied to the gate electrode (for example, the first node N1) of the driving transistor T1, the data voltage of the data line DATA applied to the gate electrode of the driving transistor T1 is not affected, thereby preventing ore reducing degradation of display quality.

Furthermore, because the second capacitor Cst2 is located between the second node N2 and the data line DATA, a decrease in luminance of a light-emitting device due to a parasitic capacitor of an electrode overlapping the first node N1 may be prevented or reduced. Accordingly, degradation of display quality may be prevented or reduced.

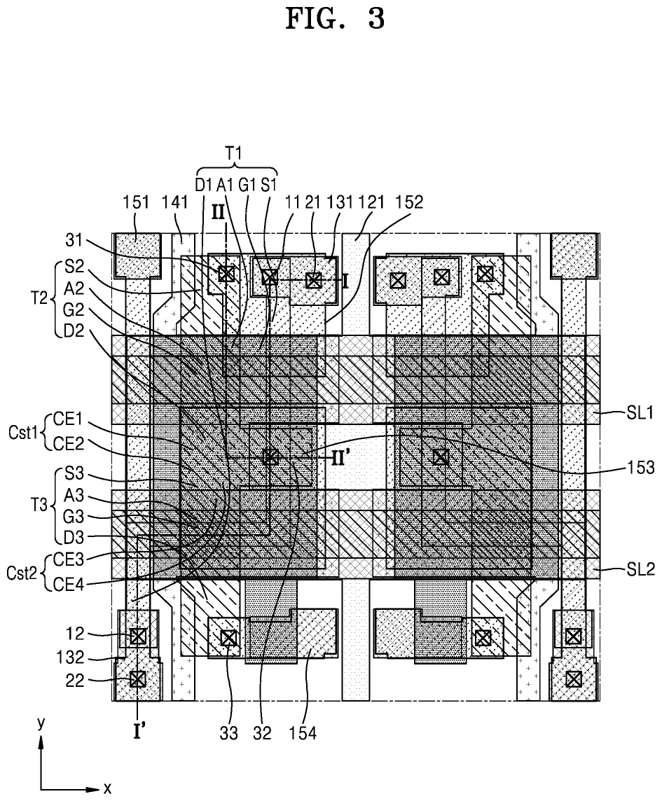

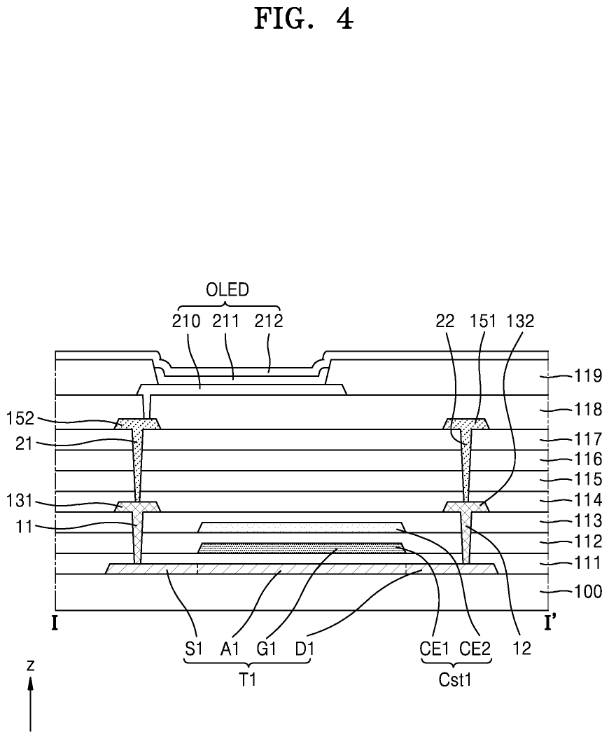

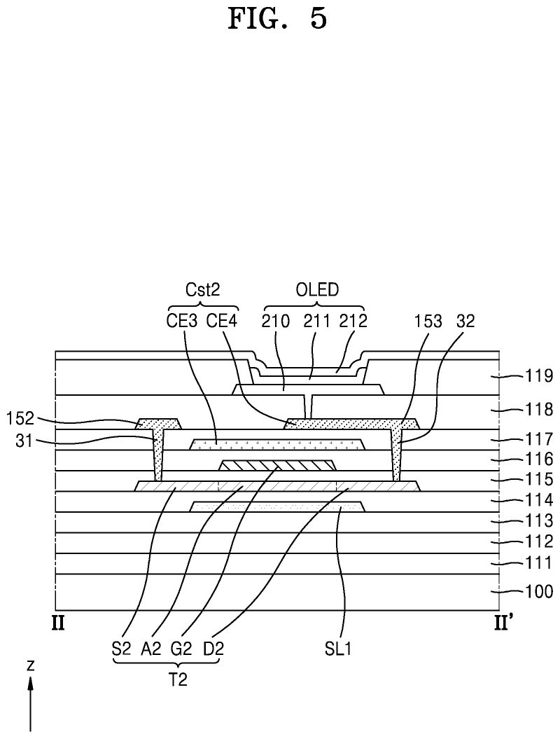

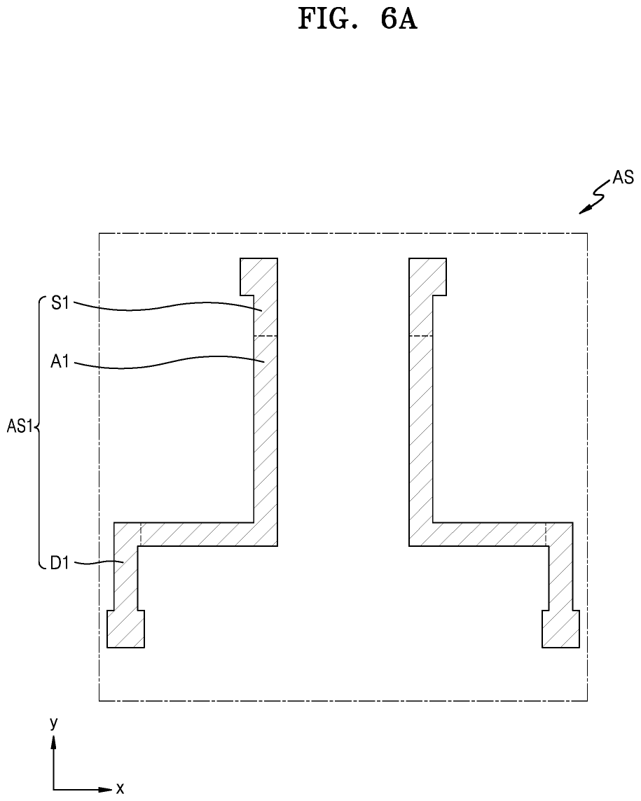

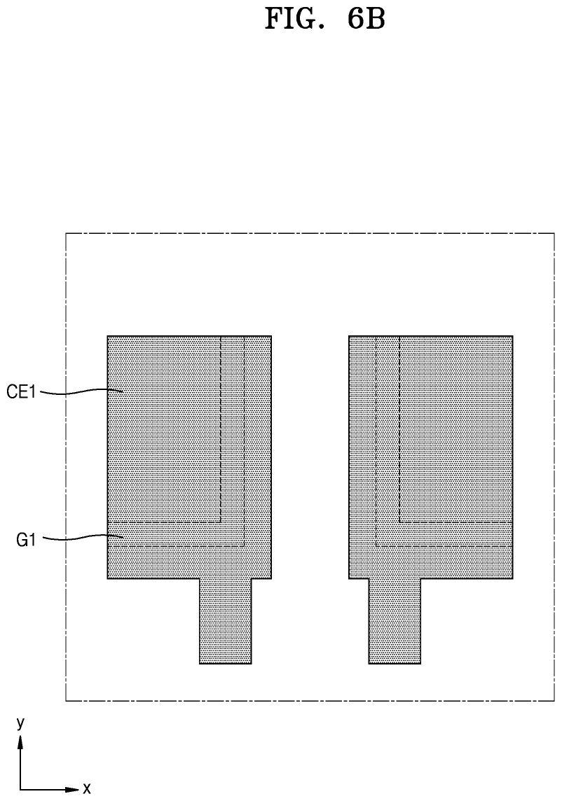

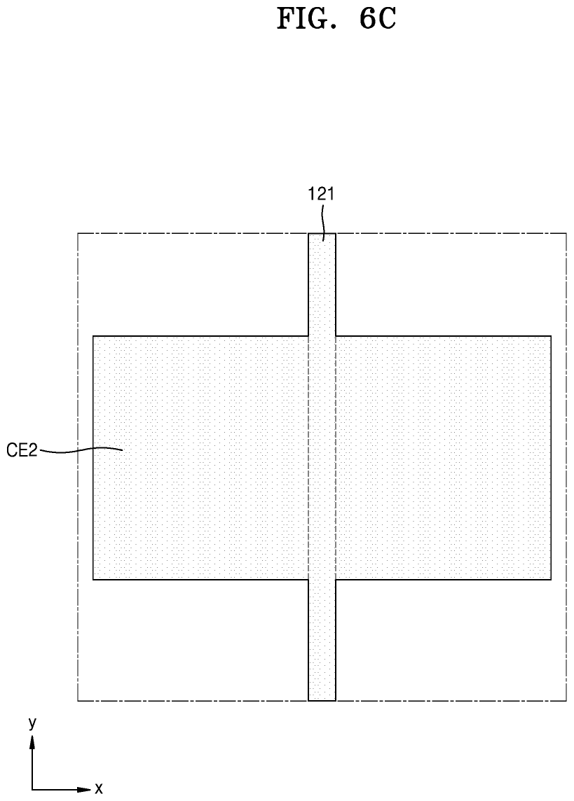

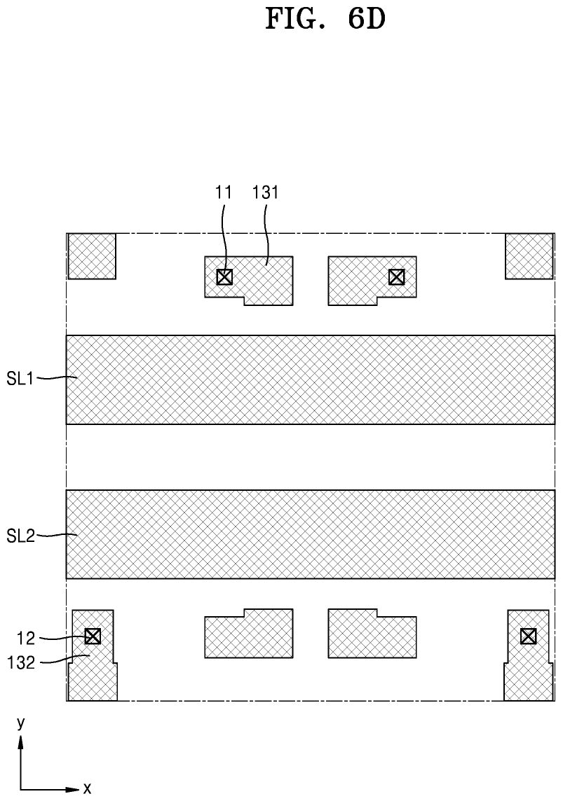

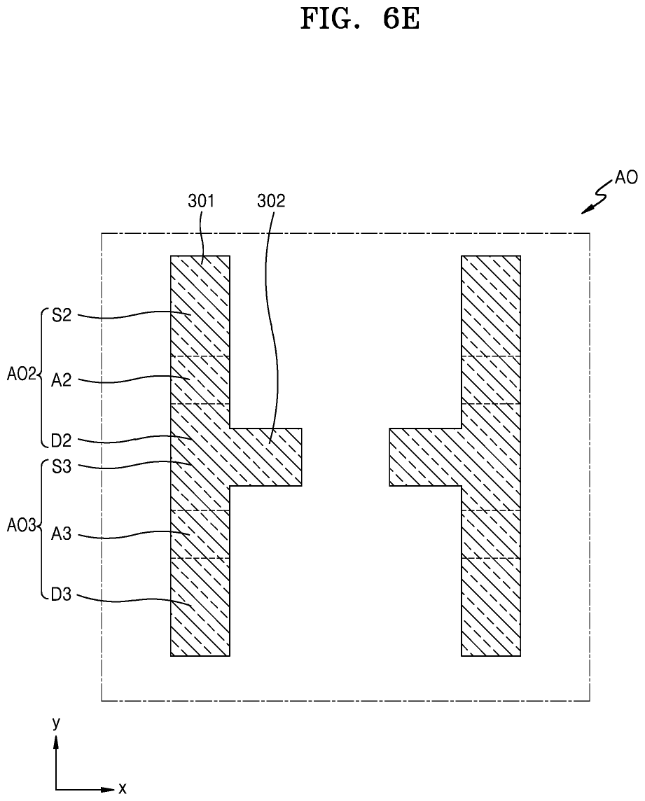

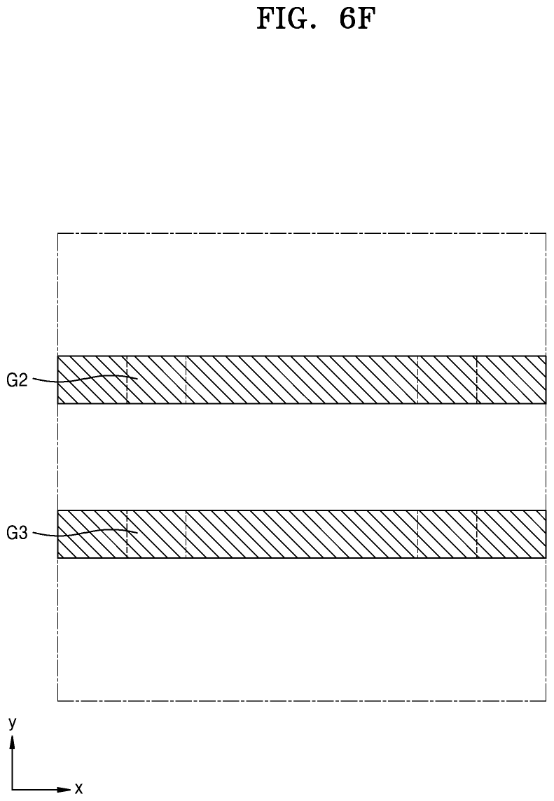

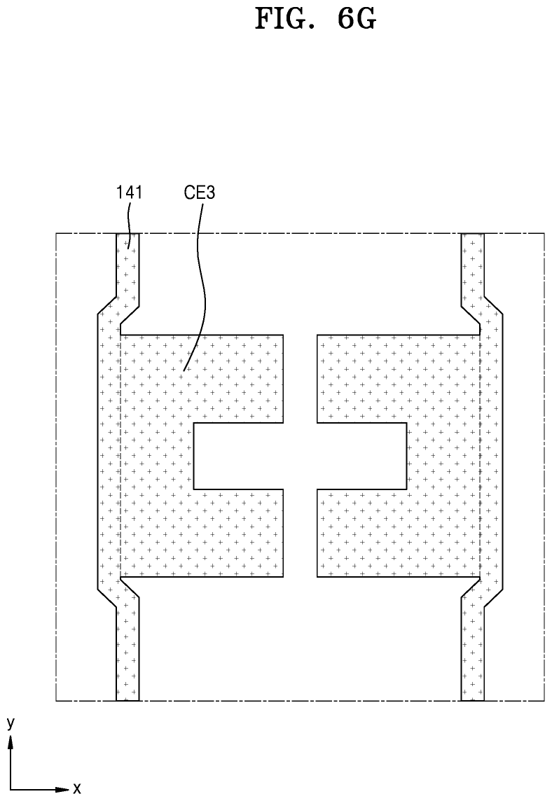

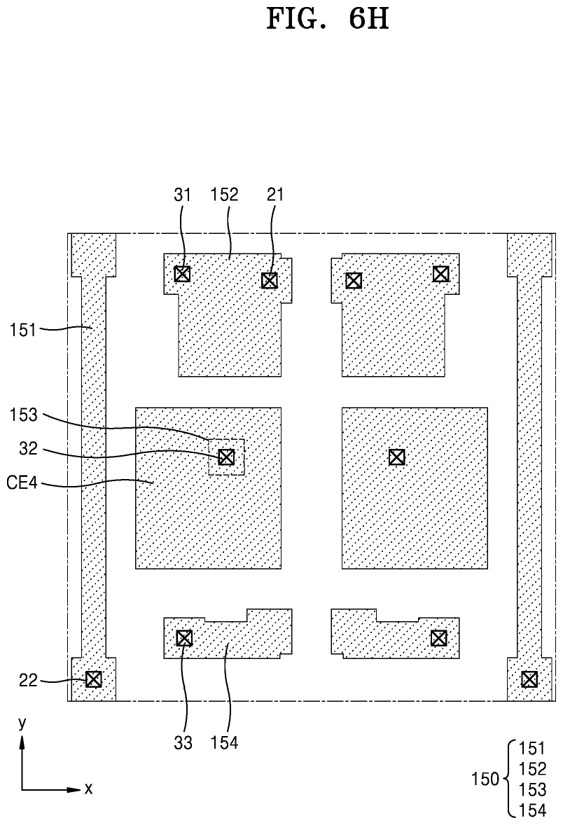

FIG. 3 is a schematic plan view schematically illustrating positions of thin-film transistors and capacitors located in a pair of pixel circuits of a display apparatus, according to an embodiment. FIG. 4 is a schematic cross-sectional view taken along line I-I′ of FIG. 3. FIG. 5 is a schematic cross-sectional view taken along line II-II′ of FIG. 3. FIGS. 6A to 6H are schematic plan views schematically illustrating devices of FIG. 3 according to layers.

In FIG. 3, a pair of pixel circuits arranged or disposed in the same row in adjacent columns are illustrated. In FIG. 3, a pixel circuit of a pixel located in a left pixel area and a pixel circuit of a pixel located in a right pixel area are symmetrical each other.

Referring to FIGS. 3, and 6A to 6H, a pixel circuit of a display apparatus according to an embodiment may include a first scan line SL1 and a second scan line SL2 extending in a first direction (for example, an x direction or a −x direction), and may include a driving voltage line ELVDD 151, a data line 141, and an initialization voltage line VINT 121 extending in a second direction (for example, a y direction or a −y direction) intersecting the first direction (for example, the x direction or the −x direction).

Also, the pixel circuit may a first transistor T1, a second transistor T2, a third transistor T3, a first capacitor Cst1, and a second capacitor Cst2. The first transistor T1 may be a driving transistor, and the second transistor T2 and the third transistor T3 may be switching transistors.

In an embodiment, the first transistor T1 may be a thin-film transistor including a silicon semiconductor. Each of the second transistor T2 and the third transistor T3 may be a thin-film transistor including an oxide semiconductor.

A semiconductor layer AS of the first transistor T1 may be formed of polycrystalline silicon. The semiconductor layer AS of the first transistor T1 may be curved into any of various shapes. The semiconductor layer AS of the first transistor T1 may include a channel region, and a source region and a drain region on both sides of the channel region. For example, the source region and the drain region may be doped with impurities, and the impurities may include N-type impurities or P-type impurities. Each source region and each drain region may respectively correspond to a source electrode and a drain electrode. The source region and the drain region may be changed from each other according to the characteristics of the transistor. Hereinafter, the terms “source region” and “drain region” are used instead of the terms “source electrode” and “drain electrode”.

The first transistor T1 may include a first semiconductor layer AS1 and a first gate electrode G1. The first semiconductor layer AS1 may include a first channel region A1, and a first source region S1 and a first drain region D1 on both sides of the first channel region A1. The first semiconductor layer AS1 may have a curved shape, and the first channel region A1 may be formed to be longer. For example, because the semiconductor layer AS has a shape that is bent multiple times such as ‘ ⊂’, ‘2’, ‘S’, ‘M’, or ‘W’, a long channel may be formed in a narrow space. Because the first channel region A1 is formed long, a driving range of a gate voltage applied to the first gate electrode G1 may increase, a gray level of light emitted from an organic light-emitting diode OLED may be more precisely controlled, and display quality may be improved. In an embodiment, the first semiconductor layer AS1 may be provided in a straight shape, rather than a bent shape. The first gate electrode G1 having an island shape overlaps the first channel region A1 with a first interlayer insulating layer 111 (see FIG. 4) therebetween.

The first source region S1 of the first transistor T1 may be electrically connected to a second source region S2 of the second transistor T2. The first drain region D1 of the first transistor T1 may be electrically connected to the driving voltage line ELVDD 151.

A lower electrode CE1 of the first capacitor Cst1 may be provided as at least a part of the first gate electrode G1. In other words, the lower electrode CE1 of the first capacitor Cst1 and the first gate electrode G1 of the first transistor T1 may be integral with each other. An upper electrode CE2 of the first capacitor Cst1 may be located on the first gate electrode G1.

A fourth interlayer insulating layer 114 (see FIG. 4) may be located on the first transistor T1 including a silicon semiconductor, and the second transistor T2 and the third transistor T3 each including an oxide semiconductor may be located on the fourth interlayer insulating layer 114.

In an embodiment, an equivalent circuit diagram of one pixel of the display apparatus may include three transistors (for example, T1, T2, and T3) and two capacitors (for example, Cst1 and Cst2) to achieve ultra-high resolution. Also, in order to realize an ultra-high resolution display apparatus, signals may be applied to the first and second scan lines SL1 and SL2 simultaneously, not sequentially. In case that the display apparatus with simultaneous light emission is realized, leakage current of a transistor may be generated and thus, a voltage of the transistor may be lowered. Due to an influence difference of the leakage current generated in the transistor, a luminance difference may occur between an upper portion and a lower portion of the display apparatus.

An oxide semiconductor layer may generate less leakage current than a silicon semiconductor due to material properties. Because each of the second transistor T2 and the third transistor T3 may include an oxide semiconductor, leakage current generated in a transistor may be prevented, a voltage of the transistor may be maintained, and thus, a luminance difference between an upper portion and a lower portion of the display apparatus may be prevented.

Oxide semiconductor layers AO of the second transistor T2 and the third transistor T3 may be located on a same layer and may include a same material. For example, the oxide semiconductor layer AO may be formed of an oxide semiconductor.

The oxide semiconductor layer AO may include a channel region, and a source region and a drain region on both sides of the channel region. For example, the source region and the drain region may be regions having a high carrier concentration due to plasma treatment. Each source region and each drain region may respectively correspond to a source electrode and a drain electrode. Hereinafter, the terms “source region” and “drain region” are used instead of the terms “source electrode” and “drain electrode”.

The second transistor T2 may include a second semiconductor layer A02 including an oxide semiconductor and a second gate electrode G2. The second semiconductor layer A02 may include a second channel region A2, and a second source region S2 and a second drain region D2 on both sides of the second channel region A2. The second source region S2 may be connected to the first source region S1 of the first transistor T1. The second drain region D2 of the second transistor T2 may be connected to a third source region S3 of the third transistor T3. The second gate electrode G2 of the second transistor T2 may be connected to the first scan line SL1.

The third transistor T3 may include a third semiconductor layer A03 including an oxide semiconductor and a third gate electrode G3. The third semiconductor layer A03 may include a third channel region A3, and the third source region S3 and a third drain region D3 on both sides of the third channel region A3. The third source region S3 may be connected to the second drain region D2 of the second transistor T2. The third drain region D3 of the third transistor T3 may be electrically connected to the lower electrode CE1 of the first capacitor Cst1.

The second capacitor Cst2 may be located on the second transistor T2. A lower electrode CE3 and an upper electrode CE4 of the second capacitor Cst2 may be located on the second transistor T2. The lower electrode CE3 and the upper electrode CE4 of the second capacitor Cst2 may overlap each other.

FIGS. 4 and 5 are schematic cross-sectional views illustrating portions corresponding to the first transistor T1, the second transistor T2, the first capacitor Cst1, the second capacitor Cst2, and the organic light-emitting diode OLED, and some or a number of members may be omitted.

The substrate 100 may include a glass material, a ceramic material, a metal material, plastic, or a flexible or bendable material. In case that the substrate 100 is flexible or bendable, the substrate 100 may include a polymer resin such as polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP).

The substrate 100 may have a single or multi-layer structure including the above material, and in case that the substrate 100 has a multi-layer structure, the substrate 100 may further include an inorganic layer. For example, although not shown, the substrate 100 may include a first organic base layer, a first inorganic barrier layer, a second organic base layer, and a second inorganic barrier layer. Each of the first organic base layer and the second organic base layer may include a polymer resin. Each of the first inorganic barrier layer and the second inorganic barrier layer which is a barrier layer for preventing penetration of an external foreign material may have a single or multi-layer structure including an inorganic material such as silicon nitride (SiNₓ) or silicon oxide (SiOₓ).

Although not shown, in an embodiment, a buffer layer may be located on the substrate 100. The buffer layer may increase a flatness of a top surface of the substrate 100, and may include an oxide film such as silicon oxide (SiOₓ), a nitride film such as silicon nitride (SiNₓ), or silicon oxynitride (SiOₓN_{y}).

The first semiconductor layer AS1 of the first transistor T1 may be located on the substrate 100 and the buffer layer as shown in FIG. 6A. The first semiconductor layer AS1 may include the first channel region A1 of the first transistor T1, and the first source region S1 and the first drain region D1 on both sides of the first channel region A1.

The first interlayer insulating layer 111 may be located on the first semiconductor layer AS1. The first interlayer insulating layer 111 may include an inorganic material including oxide or nitride. For example, the first interlayer insulating layer 111 may include at least one of silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂).

As shown in FIG. 6B, the first gate electrode G1 of the first transistor T1 may be located on the first interlayer insulating layer 111. Also, the lower electrode CE1 of the first capacitor Cst1 may be located on the first interlayer insulating layer 111. The lower electrode CE1 of the first capacitor Cst1 and the first gate electrode G1 of the first transistor T1 may be located on a same layer and may include a same material. The lower electrode CE1 of the first capacitor Cst1 and the first gate electrode G1 of the first transistor T1 may be integral with each other.

Each of the first gate electrode G1 of the first transistor T1 and the lower electrode CE1 of the first capacitor Cst1 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A second interlayer insulating layer 112 may be located on the first gate electrode G1 and the lower electrode CE11 of the first capacitor Cst1. The second interlayer insulating layer 112 may include an inorganic material including oxide or nitride. For example, the second interlayer insulating layer 112 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

The upper electrode CE2 of the first capacitor Cst1 may be located on the second interlayer insulating layer 112 to overlap the lower electrode CE1 of the first capacitor Cst1 as shown in FIG. 6C. Also, an initialization voltage line 121 may be located on the second interlayer insulating layer 112. The initialization voltage line 121 and the upper electrode CE2 of the first capacitor Cst1 may be located on a same layer and may include a same material. The initialization voltage line 121 and the upper electrode CE2 of the first capacitor Cst1 may be integral with each other.

Each of the upper electrode CE2 of the first capacitor Cst1 and the initialization voltage line 121 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A third interlayer insulating layer 113 may be located on the upper electrode CE2 of the first capacitor Cst1 and the initialization voltage line 121. The third interlayer insulating layer 113 may include oxide or nitride. For example, the third interlayer insulating layer 113 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

A first bridge metal layer 131, a second bridge metal layer 132, the first scan line SL1, and the second scan line SL2 may be located on the third interlayer insulating layer 113, as shown in FIG. 6D. The first scan line SL1 and the second scan line SL2 may extend in the first direction (for example, the x direction or the −x direction) in a plan view.

The first bridge metal layer 131 and the second bridge metal layer 132 may be electrically connected to the first semiconductor layer AS1 of the first transistor T1 through contact holes 11 and 12. In detail, the first bridge metal layer 131 may be electrically connected to the first source region S1 of the first transistor T1 through the contact hole 11. The second bridge metal layer 132 may be electrically connected to the first drain region D1 of the first transistor T1 through the contact hole 12.

In order to realize an ultra-high resolution display apparatus, the number of pixels located in a display area of the display apparatus may be greater than that of a general display apparatus, and thus, wirings in the ultra-high resolution display apparatus may be more integrated than in the general display apparatus. Because wirings are more integrated in the ultra-high resolution display apparatus, many stepped portions may be formed in a process of patterning metal layers, and thus, a lower inorganic film may increase in the ultra-high resolution display apparatus due to chemical mechanical polishing (CMP). Due to the increase in the lower inorganic film in the ultra-high resolution display apparatus, a first conductive pattern layer 150 including a driving voltage line 151 (see FIG. 6H) and the first transistor T1 located at the bottom may not be connected through one contact hole. In an embodiment, due to the first and second bridge metal layers 131 and 132 between the first transistor T1 and the first conductive pattern layer 150 and contact holes 11, 12, 21, and 22 that connect the first and second bridge metal layers 131 and 132, the first semiconductor layer AS1 of the first transistor T1, and the first conductive pattern layer 150, the first transistor T1 and the first conductive pattern layer 150 may be electrically connected to each other. In other words, the first transistor T1 and the first conductive pattern layer 150 may be electrically connected to each other via the first and second bridge metal layers 131 and 132.

At least a part of the first scan line SL1 and the second scan line SL2 may overlap at least a part of the oxide semiconductor layers AO of the second transistor T2 and the third transistor T3 to be located on the first scan line SL1 and the second scan line SL2. In detail, at least a part of the first scan line SL1 overlapping at least a part of the second semiconductor layer A02 of the second transistor T2 may function as a lower gate electrode of the second transistor T2. Also, at least a part of the second scan line SL2 overlapping at least a part of the third semiconductor layer A03 of the third transistor T3 may function as a lower gate electrode of the third transistor T3.

The initialization voltage line 121 may be located under or below the second transistor T2 and the third transistor T3. Because a signal of the initialization voltage line 121 enters while being repeatedly turned on and off, it may affect the oxide semiconductor layers AO of the second transistor T2 and the third transistor T3 located on the initialization voltage line 121. In order to prevent the influence of a signal of the initialization voltage line 121 located under or below the oxide semiconductor layers AO of the second transistor T2 and the third transistor T3 on the oxide semiconductor layers AO of the second transistor T2 and the third transistor T3, the first scan line SL1 and the second scan line SL2 between the initialization voltage line 121 and the oxide semiconductor layers AO of the second transistor T2 and the third transistor T3 may overlap at least a part of the oxide semiconductor layers AO of the second transistor T2 and the third transistor T3.

The first scan line SL1, the second scan line SL2, the first bridge metal layer 131, and the second bridge metal layer 132 may be located on a same layer and may include a same material. Each of the first scan line SL1, the second scan line SL2, the first bridge metal layer 131, and the second bridge metal layer 132 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The fourth interlayer insulating layer 114 may be located on the first scan line SL1, the second scan line SL2, the first bridge metal layer 131, and the second bridge metal layer 132. The fourth interlayer insulating layer 114 may include oxide or nitride. For example, the fourth interlayer insulating layer 114 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

The oxide semiconductor layer AO including an oxide semiconductor may be located on the fourth interlayer insulating layer 114 as shown in FIG. 6E. The oxide semiconductor layer AO may include a Zn oxide-based material such as Zn oxide, In—Zn oxide, or Ga—In—Zn oxide. In an embodiment, the semiconductor layer AO may include an In—Ga—Zn-O (IGZO), In—Sn—Zn—O (ITZO), or In—Ga—Sn—Zn—O (IGTZO) semiconductor containing a metal such as indium (In), gallium (Ga), or tin (Sn) in ZnO.

Each of the oxide semiconductor layers AO of the second transistor T2 and the third transistor T3 may include a channel region, and a source region and a drain region on both sides of the channel region. The source region and the drain region of each of the second transistor T2 and the third transistor T3 may be formed by adjusting a carrier concentration of an oxide semiconductor to make conductive. For example, the source region and the drain region of each of the second transistor and the third transistor may be formed by increasing a carrier concentration through plasma treatment using a hydrogen (H)-based gas, a fluorine (F)-based gas, or a combination thereof on an oxide semiconductor.

The oxide semiconductor layer AO may include the second channel region A2, the second source region S2, and the second drain region D2 which are the second semiconductor layer AO2 of the second transistor T2, and the third channel region A3, the third source region S3, and the third drain region D3 which are the third semiconductor layer AG3 of the third transistor T3. For example, the channel region, the source region, and the drain region of each of the second transistor T2 and the third transistor T3 may be some or a number of portions of the oxide semiconductor layer AO.

The oxide semiconductor layer AO may include a first portion 301 extending in the second direction (for example, the y direction or the −y direction) and a second portion 302 protruding from the first portion 301 in the first direction (for example, the x direction or the −x direction). In an ultra-high resolution display apparatus, the oxide semiconductor layer AO may include the second portion 302 protruding from the first portion 301 in the first direction (for example, the x direction or the −x direction), and the second node N2 where the second drain region D2 of the second transistor T2 and the third source region S3 of the third transistor T3 are connected to each other may be located on the second portion 302, and thus, the display apparatus may integrate many wirings and achieve ultra-high resolution. Because the second node N2 where the second drain region D2 of the second transistor T2 and the third source region S3 f the third transistor T3 are connected to each other is located on the second portion 302 of the oxide semiconductor layer AO, the second portion 302 of the oxide semiconductor layer AO may be located between the second channel region A2 of the second transistor T2 and the third channel region A3 of the third transistor T3. In other words, the second portion 302 of the oxide semiconductor layer AO may be located between the second gate electrode G2 of the second transistor T2 and the third gate electrode G3 of the third transistor T3.

A fifth interlayer insulating layer 115 may be located on the oxide semiconductor layer AO. The fifth interlayer insulating layer 115 may include oxide or nitride. For example, the third interlayer insulating layer may include at least one of silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂).

The second gate electrode G2 of the second transistor T2 and the third gate electrode G3 of the third transistor T3 may be located on the fifth interlayer insulating layer 115, as shown in FIG. 6F. The second gate electrode G2 and the third gate electrode G3 may extend in the first direction (for example, the x direction or the −x direction) in a plan view.

Each of the second gate electrode G2 of the second transistor T2 and the third gate electrode G3 of the third transistor T3 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A sixth interlayer insulating layer 116 may be located on the second gate electrode G2 of the second transistor T2 and the third gate electrode G3 of the third transistor T3. The sixth interlayer insulating layer 116 may include an inorganic material including oxide or nitride. For example, the sixth interlayer insulating layer 116 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

A data line 141 and the lower electrode CE3 of the second capacitor Cst2 may be located on the sixth interlayer insulating layer 116, as shown in FIG. 6G. The data line 141 and the lower electrode CE3 of the second capacitor Cst2 may be located on a same layer and may include a same material. In other words, the data line 141 and the lower electrode CE3 of the second capacitor Cst2 may be integral with each other.

Each of the data line 141 and the lower electrode CE3 of the second capacitor Cst2 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A seventh interlayer insulating layer 117 may be located on the data line 141 and the lower electrode CE3 of the second capacitor Cst2. The seventh interlayer insulating layer 117 may include an inorganic material including oxide or nitride. For example, the seventh interlayer insulating layer 117 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

The first conductive pattern layer 150 and the upper electrode CE4 of the second capacitor Cst2 may be located on the seventh interlayer insulating layer 117, as shown in FIG. 6H. The first conductive pattern layer 150 may include a 1-1 conductive pattern layer 151, a 1-2 conductive pattern layer 152, a 1-3 conductive pattern layer 153, and a 1-4 conductive pattern layer 154.

The 1-1 conductive pattern layer 151 may be provided as the driving voltage line ELVDD. The 1-1 conductive pattern layer 151 may be electrically connected to the second bridge metal layer 132 through the contact hole 22. The second bridge metal layer 132 may be electrically connected to the first drain region D1 of the first transistor T1 through the contact hole 12. In conclusion, the 1-1 conductive pattern layer 151 may be electrically connected to the first drain region D1 of the first transistor T1, via the second bridge metal layer 132, through the contact holes 12 and 22. In other words, the driving voltage line EVLDD may be electrically connected to the first drain region D1 of the first transistor T1, through the contact holes 12 and 22.

The 1-2 conductive pattern layer 152 may be electrically connected to the first bridge metal layer 131 through the contact hole 21. The first bridge metal layer 131 may be electrically connected to the first source region S1 of the first transistor T1 through the contact hole 11. In conclusion, the 1-2 conductive pattern layer 152 may be electrically connected to the first source region S1 of the first transistor T1, via the first bridge metal layer 131, through the contact holes 11 and 21.

Also, the 1-2 conductive pattern layer 152 may be electrically connected to the second source region S2 of the second transistor T2 through a contact hole 31. In conclusion, the first source region S1 of the first transistor T1 and the second source region S2 of the second transistor T2 may be electrically connected to each other, through the 1-2 conductive pattern layer 152.

The 1-3 conductive pattern layer 153 may be electrically connected to the second drain region D2 of the second transistor T2, through a contact hole 32. Also, the 1-3 conductive pattern layer 153 may be electrically connected to the third source region S3 of the third transistor T3, through the contact hole 32. In other words, the 1-3 conductive pattern layer 153 may be the second node N2 where the second drain region D2 of the second transistor T2 and the third source region S3 of the third transistor T3 are connected to each other. Also, the upper electrode CE4 of the second capacitor Cst2 may be integral with the 1-3 conductive pattern layer 153.

The 1-4 conductive pattern layer 154 may be electrically connected to the third drain region D3 of the third transistor T3 through a contact hole 33. Although not shown, the third drain region D3 of the third transistor T3 may be electrically connected to the first capacitor Cst1, through the 1-4 conductive pattern layer 154.

Each of the upper electrode CE4 of the second capacitor Cst2 and the first conductive pattern layer 150 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A planarization layer 118 may be located on the upper electrode CE4 of the second capacitor Cst2 and the first conductive pattern layer 150. The planarization layer 118 may include an organic material such as acryl, benzocyclobutene (BCB), polyimide, or hexamethyldisiloxane (HMDSO). The planarization layer 118 functions as a protective film covering the first to third transistors and a top surface of the planarization layer 118 is to be planarized. The planarization layer 118 may have a single or multi-layer structure.

A pixel-defining film 119 may be located on the planarization layer 118. The pixel-defining film 119 defines a pixel by having an opening corresponding to each pixel, for example, an opening through which at least a central portion of a pixel electrode 210 is exposed. Also, the pixel-defining film 119 increases a distance between an edge of the pixel electrode 210 and a counter electrode 212 over the pixel electrode 210 to prevent an arc or the like from occurring at the edge of the pixel electrode 210. The pixel-defining film 119 may be formed of an organic material such as PI or HMDSO.

An intermediate layer 211 of the organic light-emitting diode OLED may include a low molecular weight material or a high molecular weight material. In case that the intermediate layer 211 may include a low molecular weight material, the intermediate layer 211 may have a single or stacked structure in which a hole injection layer (HIL), a hole transport layer (HTL), an emission layer (EML), an electron transport layer (ETL), and an electron injection layer (EIL) may be stacked each other, and may include any of various organic materials such as copper phthalocyanine (CuPc), N,N′-Di(napthalene-1-yl)-N,N′-diphenyl-benzidine (NPB), or tris-8-hydroxyquinoline aluminum (Alq3). These layers may be formed by using vacuum deposition.

In case that the intermediate layer 211 may include a high molecular weight material, the intermediate layer 211 may have a structure including an HTL and an EML. The HTL may include poly(3,4-ethylenedioxythiophene) (PEDOT), and the EML may include a polymer material such as a polyphenylene vinylene (PPV)-based material or a polyfluorene-based material. The intermediate layer 211 may be formed by using screen printing, inkjet printing, laser-induced thermal imaging (LITI), or the like within the spirit and the scope of the disclosure.

The intermediate layer 211 is not necessarily limited thereto, and may have any of various structures. The intermediate layer 211 may include a layer that is integrally formed over pixel electrodes 210, or may include a layer that is patterned to correspond to each of the pixel electrodes 210.

For example, the counter electrode 212 may be integrally formed in organic light-emitting diodes and may correspond to the pixel electrodes 210.

Because the organic light-emitting diodes OLED may be damaged by external moisture or oxygen, a thin-film encapsulation layer (not shown) or a sealing substrate (not shown) may be located on the organic light-emitting diodes OLED to cover and protect the organic light-emitting diodes OLED. The thin film encapsulation layer (not shown) may cover the display area DA and may extend to the outside of the display area DA. The thin-film encapsulation layer may include an inorganic encapsulation layer including at least one inorganic material and an organic encapsulation layer including at least one organic material. In an embodiment, the thin-film encapsulation layer may have a structure in which a first inorganic encapsulation layer, an organic encapsulation layer, and a second inorganic encapsulation layer may be stacked each other. The sealing substrate (not shown) may face the substrate 100, and may be adhered to the substrate 100 in the peripheral area PA by using a sealing member such as a sealant or a frit.

Also, a spacer for preventing mask damage may be further provided on the pixel-defining film 119, and various functional layers such as a polarization layer for reducing external light reflection, a black matrix, a color filter, and/or a touchscreen layer including a touch electrode may be provided on the thin-film encapsulation layer.

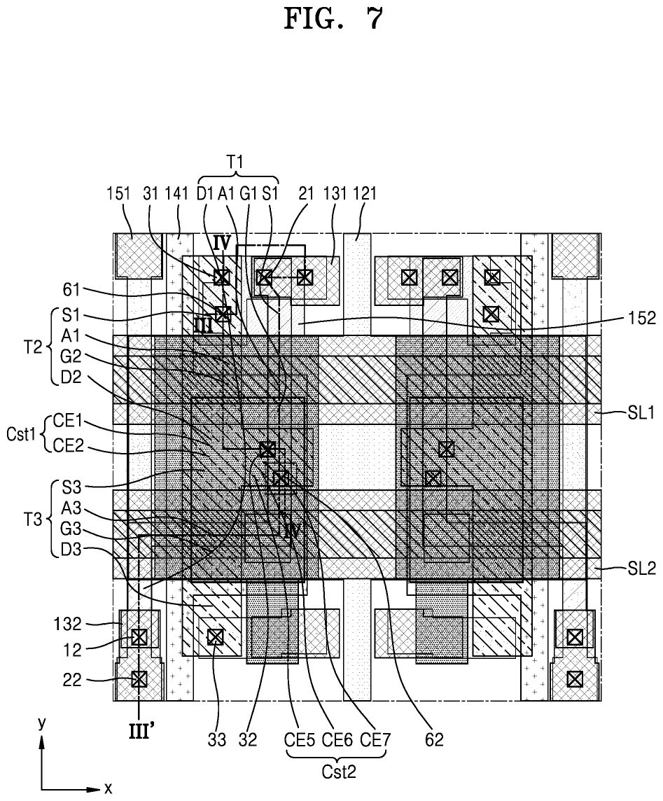

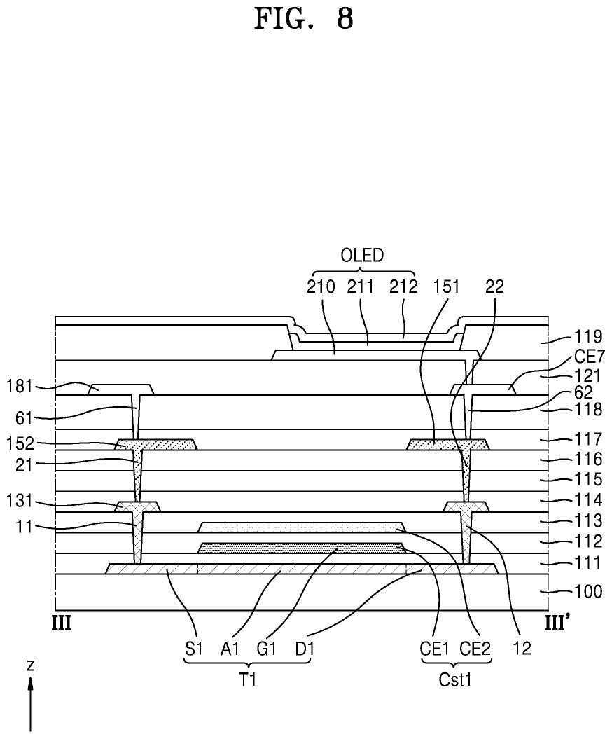

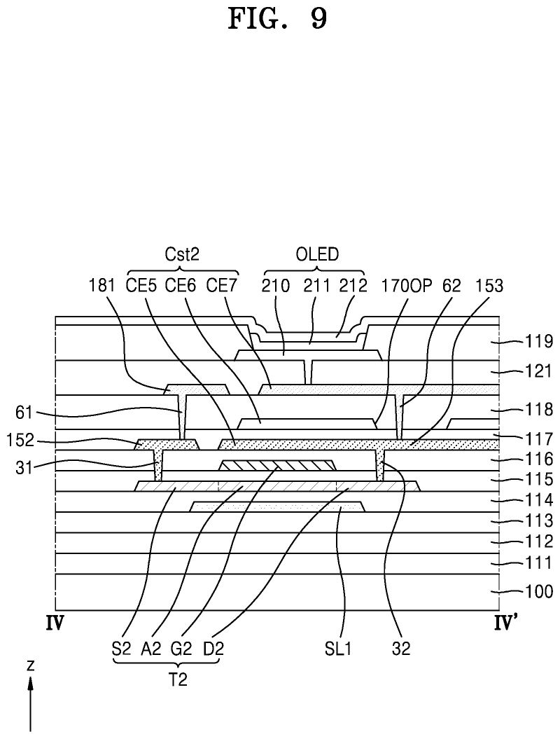

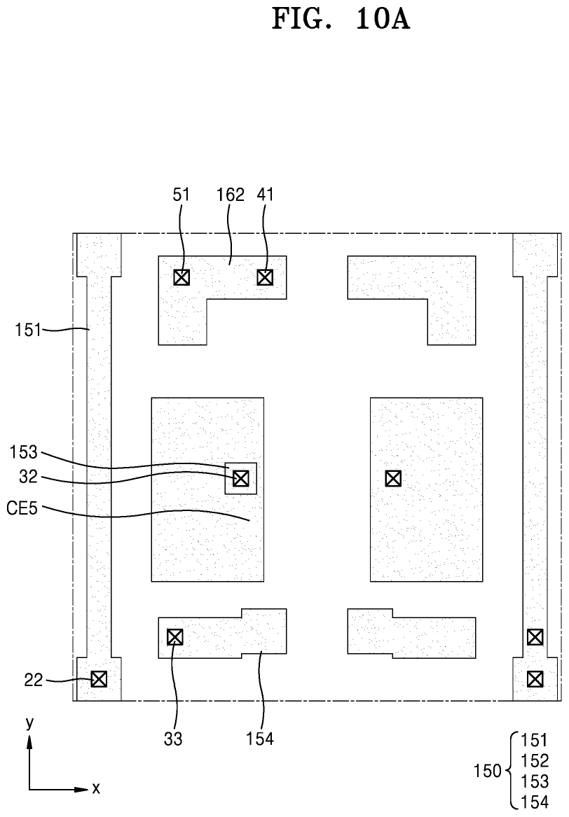

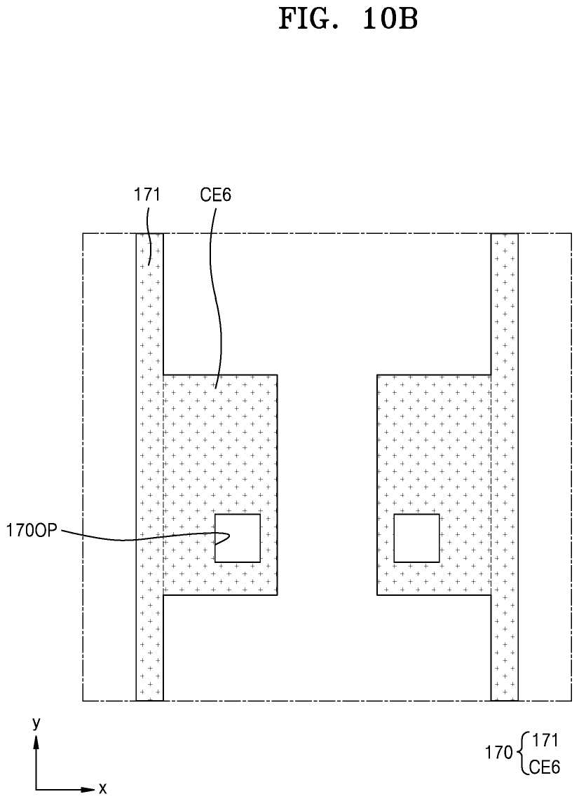

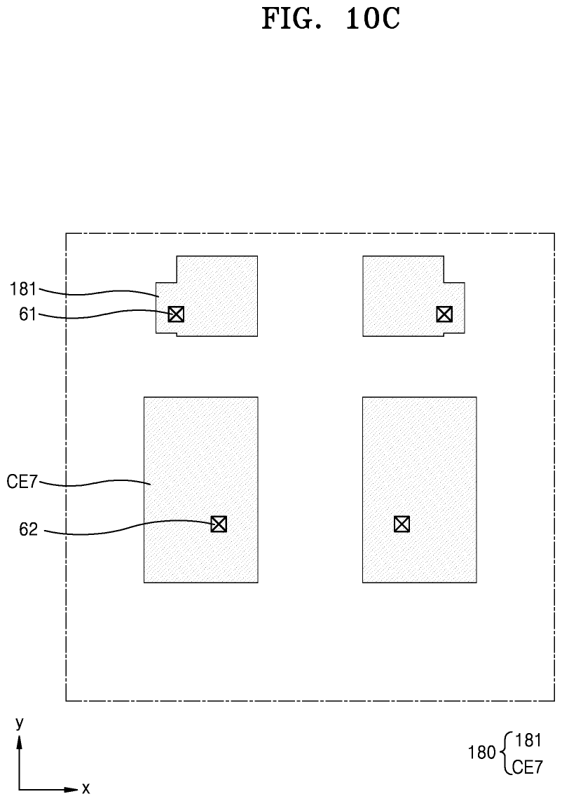

FIG. 7 is a schematic plan view schematically illustrating positions of thin-film transistors and capacitors located in a pair of pixel circuits of a display apparatus, according to an embodiment. FIG. 8 is a schematic cross-sectional view taken along line III-III′ of FIG. 7. FIG. 9 is a schematic cross-sectional view taken along line IV-IV′ of FIG. 7. FIGS. 10A to 10C are schematic plan views schematically illustrating at least some or a number of devices of FIG. 7 according to layers.

The schematic plan view of FIG. 7 is a schematic plan view obtained by combining FIGS. 6A to 6F with FIGS. 10A to 10C. In other words, an embodiment of FIG. 7 may be the same as an embodiment of FIG. 3 up to a structure in which the second transistor T2 and the third transistor T3 are located, in a plan view. However, structures on the second transistor T2 and the third transistor T3 may be different from each other. In a plan view, a structure in which the second transistor T2 and the third transistor T3 are located has been described above, and thus, a repeated description thereof will be omitted.

FIGS. 8 and 9 are schematic cross-sectional views illustrating portions corresponding to the first transistor T1, the second transistor T2, the first capacitor Cst1, the second transistor Cst2, and the organic light-emitting diode OLED of FIG. 7, and some or a number of members may be omitted.

In an embodiment, the sixth interlayer insulating layer 116 may be located on the second transistor T2 and the third transistor T3. The sixth interlayer insulating layer 116 may include an inorganic material including oxide or nitride. For example, the sixth interlayer insulating layer 116 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

The first conductive pattern layer 150 and a lower electrode CE5 of the second capacitor Cst2 may be located on the sixth interlayer insulating layer 116, as shown in FIG. 10A. The first conductive pattern layer 150 may include the 1-1 conductive pattern layer 151, the 1-2 conductive pattern layer 152, the 1-3 conductive pattern layer 153, and the 1-4 conductive pattern layer 154, like the first conductive pattern layer 150 of an embodiment of FIG. 6H. However, a shape of each first conductive pattern layer 150 may be different from that of the first conductive pattern layer 150 of an embodiment of FIGS. 7 and 6H. In detail, although the 1-2 conductive pattern layer 152 of an embodiment of FIG. 6H has a substantially quadrangular shape, the 1-2 conductive pattern layer 152 of an embodiment of FIG. 10A may have a shape obtained by horizontally inverting a ‘¬’ shape.

The 1-1 conductive pattern layer 151 may be provided as the driving voltage line ELVDD. The 1-1 conductive pattern layer 151 may be electrically connected to the second bridge metal layer 132 through the contact hole 22. The second bridge metal layer 132 may be electrically connected to the first drain region D1 of the first transistor T1 through the contact hole 12. In conclusion, the 1-1 conductive pattern layer 151 may be electrically connected to the first drain region D1 of the first transistor T1, via the second bridge metal layer 132, through the contact holes 12 and 22. In other words, the driving voltage line ELVDD may be electrically connected to the first drain region D1 of the first transistor T1, through the contact holes 12 and 22.

The 1-2 conductive pattern layer 152 may be electrically connected to the first bridge metal layer 131 through the contact hole 21. The first bridge metal layer 131 may be electrically connected to the first source region S1 of the first transistor T1 through the contact hole 11. In conclusion, the 1-2 conductive pattern layer 152 may be electrically connected to the first source region S1 of the first transistor T1, via the first bridge metal layer 131, through the contact holes 11 and 21.

Also, the 1-2 conductive pattern layer 152 may be electrically connected to the second source region S2 of the second transistor T2 through the contact hole 31. In conclusion, the first source region S1 of the first transistor T1 and the second source region S2 of the second transistor T2 may be electrically connected to each other, through the 1-2 conductive pattern layer 152.

The 1-3 conductive pattern layer 153 may be electrically connected to the second drain region D2 of the second transistor T2, through the contact hole 32. Also, the 1-3 conductive pattern layer 153 may be electrically connected to the third source region S3 of the third transistor T3, through the contact hole 32. In other words, the 1-3 conductive pattern layer 153 may be the second node N2 where the second drain region D2 of the second transistor T2 and the third source region S3 of the third transistor T3 are connected to each other. Also, the lower electrode CE5 of the second capacitor Cst2 may be integral with the 1-3 conductive pattern layer 153.

The 1-4 conductive pattern layer 154 may be electrically connected to the third drain region D3 of the third transistor T3 through the contact hole 33. Although not shown, the third drain region D3 of the third transistor T3 may be electrically connected to the first capacitor Cst1 through the 1-4 conductive pattern layer 154.

Each of the lower electrode CE5 of the second capacitor Cst2 and the first conductive pattern layer 150 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The seventh interlayer insulating layer 117 may be located on the lower electrode CE5 of the second capacitor Cst2 and the first conductive pattern layer 150. The seventh interlayer insulating layer 117 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

A third conductive pattern layer 170 may be located on the seventh interlayer insulating layer 117, as shown in FIG. 10B. The third conductive pattern layer 170 may include an intermediate electrode CE6 of the second capacitor Cst2 and a data line 171. Also, the third conductive pattern layer 170 may include an opening 1700P. At least a part of the first conductive pattern layer 150 and at least a part of a second conductive pattern layer 180 located on the third conductive pattern layer 170 may be electrically connected to each other, through a contact hole 62 (see FIG. 10C) formed in the opening 1700P of the third conductive pattern layer 170.

The third conductive pattern layer 170 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An eighth interlayer insulating layer 118 may be located on the third conductive pattern layer 170. The eighth interlayer insulating layer 118 may include an inorganic material including oxide or nitride. For example, the eighth interlayer insulating layer 118 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

The second conductive pattern layer 180 may be located on the eighth interlayer insulating layer 118 as shown in FIG. 10C. The second conductive pattern layer 180 may include a 2-1 conductive pattern layer 181 and an upper electrode CE7 of the second capacitor Cst2.

The 2-1 conductive pattern layer 181 may be electrically connected to the 1-2 conductive pattern layer 152 through a contact hole 61. The 1-2 conductive pattern layer 152 may be electrically connected to the first bridge metal layer 131 through the contact hole 21, and the first bridge metal layer 131 may be electrically connected to the first source region S1 of the first transistor T1 through the contact hole 11. Also, the 1-2 conductive pattern layer 152 electrically connected to the 2-1 conductive pattern layer 181 through the contact hole 61 may be electrically connected to the second source region S2 of the second transistor T2 through the contact hole 31. In conclusion, the first source region S1 of the first transistor T1 and the second source region S2 of the second transistor T2 may be electrically connected to each other, through the 2-1 conductive pattern layer 181 and the 1-2 conductive pattern layer 152.

The lower electrode CE5 of the second capacitor Cst2 may be provided as at least a part of the first conductive pattern layer 150, the intermediate electrode CE6 of the second capacitor Cst2 may be provided as at least a part of the third conductive pattern layer 170, and the upper electrode CE7 of the second capacitor Cst2 may be provided as at least a part of the second conductive pattern layer 180. The lower electrode CE5, the intermediate electrode CE6, and the upper electrode CE7 of the second capacitor Cst2 may overlap each other. In order to realize an ultra-high resolution display apparatus, because many wirings should be integrated in a display area, an area where a capacitor may be located may be narrow. In case that the capacitor including an upper electrode, an intermediate electrode, and a lower electrode is located in the narrow area, the capacitor with a large capacity may be implemented in the narrow area, and an ultra-high resolution display apparatus may be implemented by integrating many pixel circuits in the display apparatus.

The upper electrode CE7 of the second capacitor Cst2 may be electrically connected to the lower electrode CE5 of the second capacitor Cst2, through the contact hole 62 located in the opening 1700P of the third conductive pattern layer 170. Also, the 1-3 conductive pattern layer 153 integral with the lower electrode CE5 of the second capacitor Cst2 may be electrically connected to the second drain region D2 of the second transistor T2, through the contact hole 32.

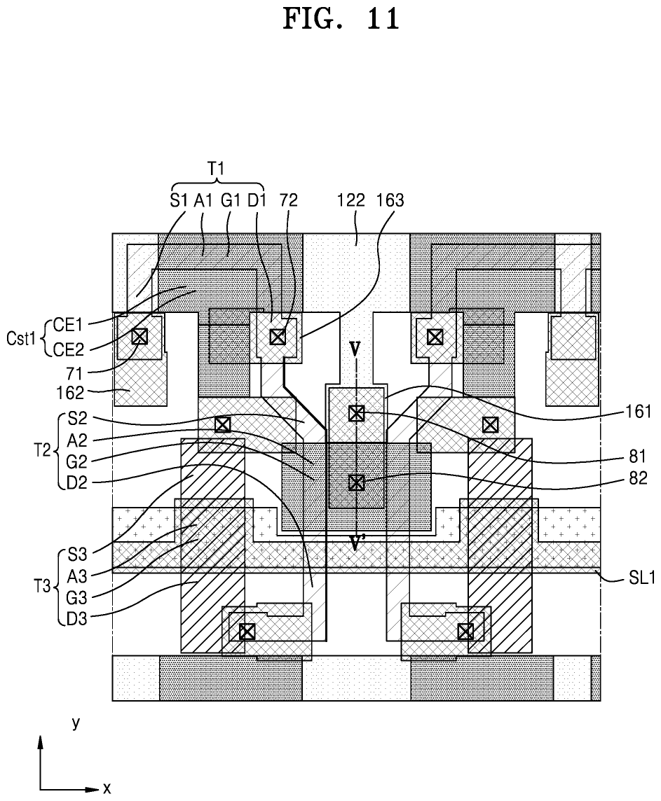

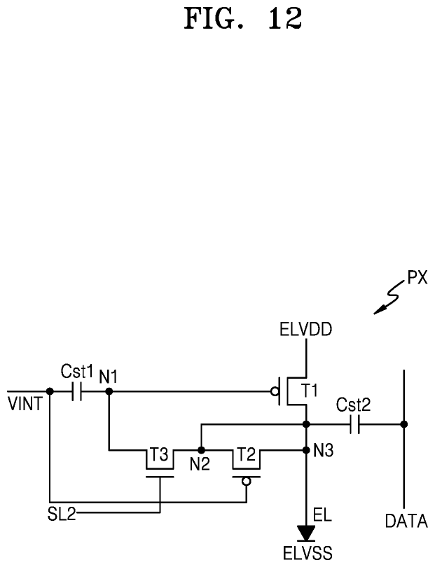

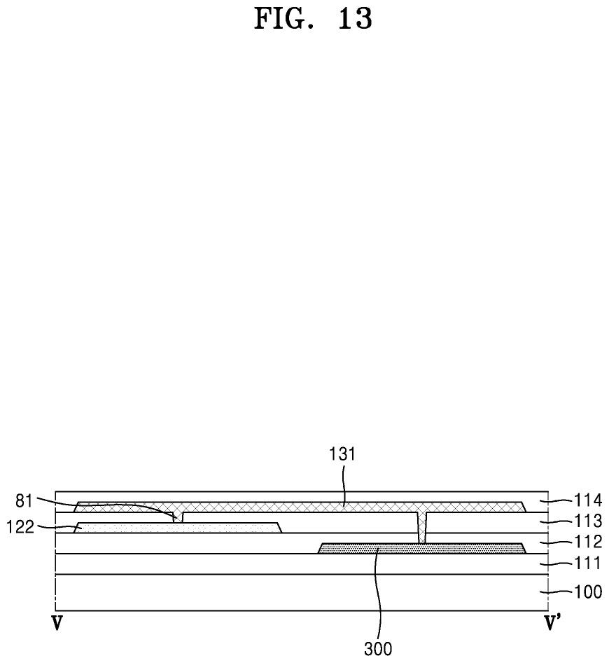

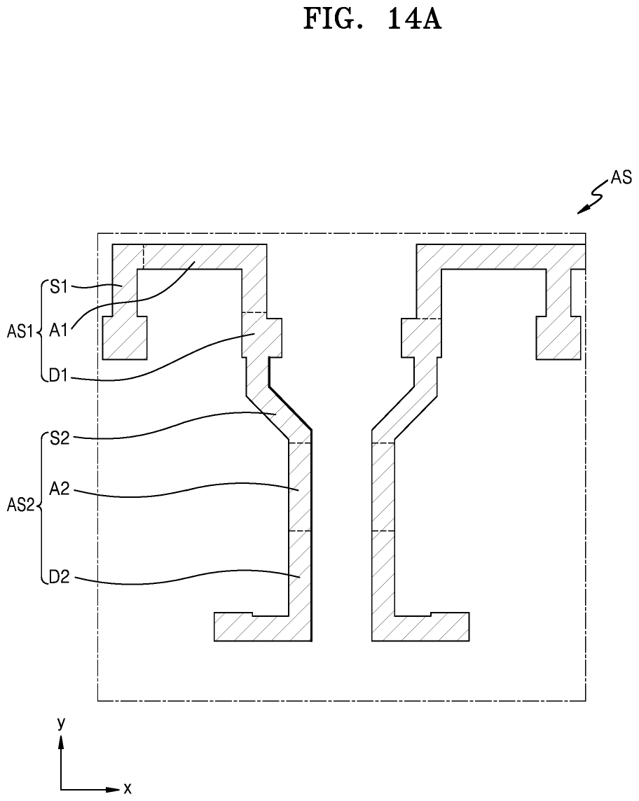

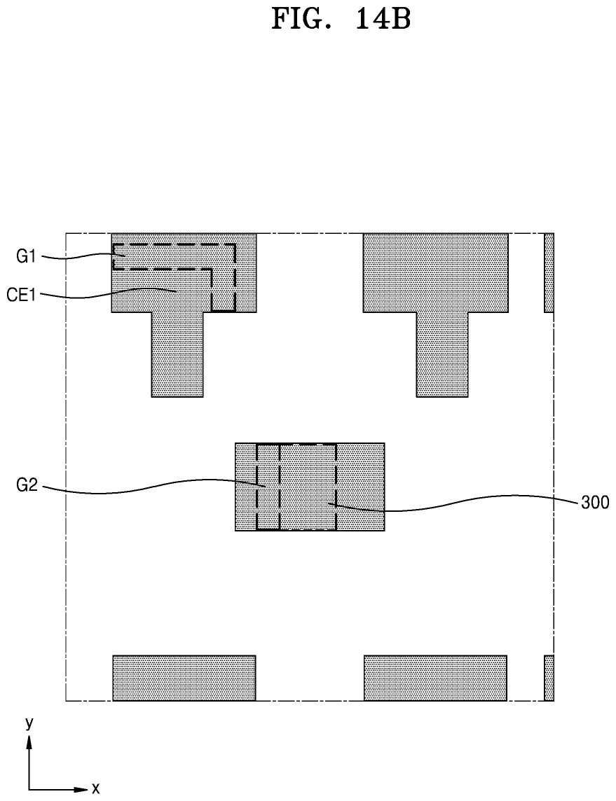

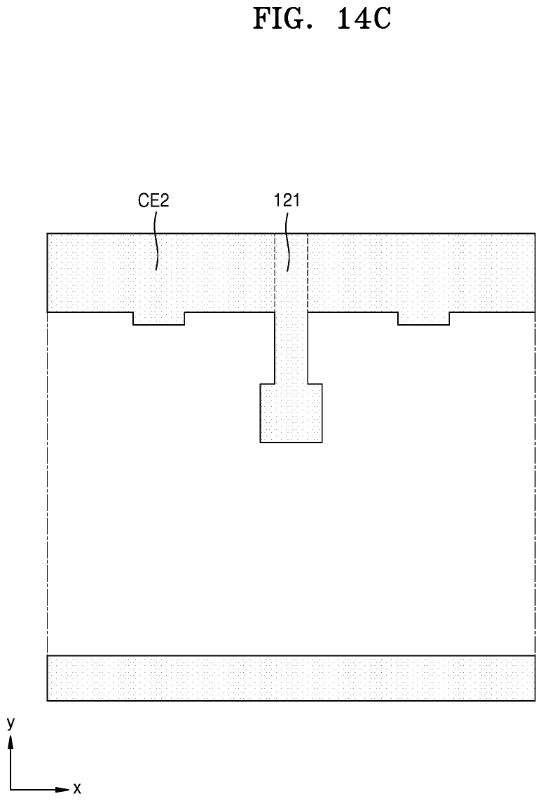

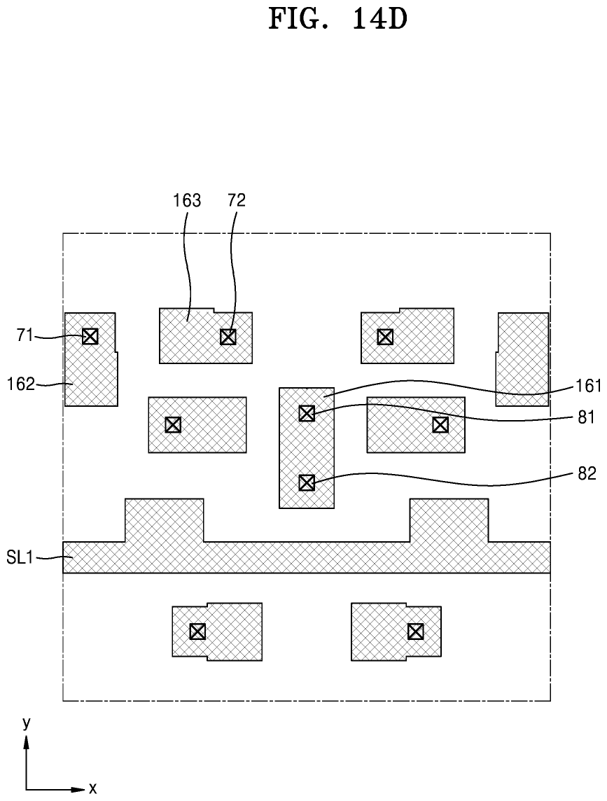

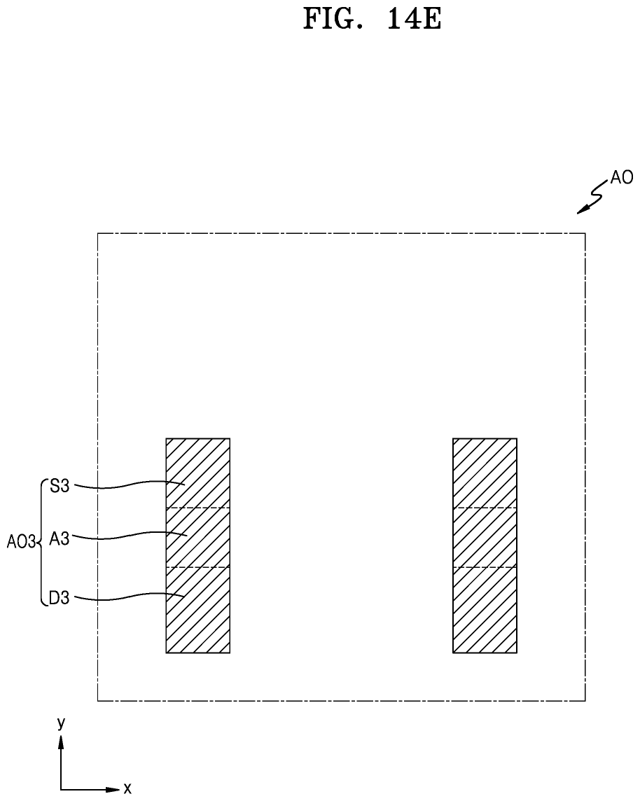

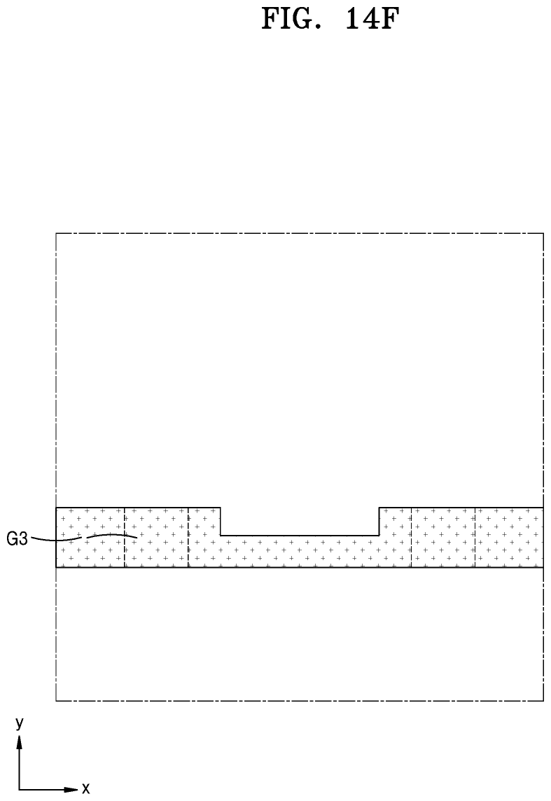

FIG. 11 is a schematic plan view schematically illustrating thin-film transistors and capacitors located in a pair of pixel circuits of a display apparatus, according to an embodiment. FIG. 12 is a schematic diagram of an equivalent circuit schematically illustrating one pixel of an embodiment of FIG. 11. FIG. 13 is a schematic cross-sectional view taken along line V-V′ of FIG. 11. FIGS. 14A to 14F are schematic plan views schematically illustrating devices of FIG. 11 according to layers.

The schematic diagram of the equivalent circuit of FIG. 12 may be the same as the schematic diagram of the equivalent circuit of FIG. 2 except that the second transistor T2 is a thin-film transistor including a silicon semiconductor rather than an oxide semiconductor, and the initialization voltage line VINT and the first scan line SL1 are connected to each other and shared, and thus, a description thereof will be omitted.

The semiconductor layers AS of the first transistor T1 and the second transistor T2 may be located on the substrate 100 and the buffer layer as shown in FIG. 14A. Each of the semiconductor layers AS of the first transistor T1 and the second transistor T2 may be formed of polycrystalline silicon. The semiconductor layers AS of the first transistor T1 and the second transistor T2 may be located on a same layer and may include a same material.

Each of the semiconductor layers AS of the first transistor T1 and the second transistor T2 may be curved into any of various shapes. Each of the semiconductor layers AS of the first transistor T1 and the second transistor T2 may include a channel region, and a source region and a drain region on both sides of the channel region. For example, the source region and the drain region may be doped with impurities, and the impurities may include N-type impurities or P-type impurities. Each source region and each drain region may respectively correspond to a source electrode and a drain electrode. The source region and the drain region may be changed from each other according to the characteristics of the transistor. Hereinafter, the terms “source region” and “drain region” are used instead of the terms “source electrode” and “drain electrode”.

The first transistor T1 may include the first semiconductor layer AS1 and the first gate electrode G1. The first semiconductor layer AS1 may include the first channel region A1, and the first source region S1 and the first drain region D1 on both sides of the first channel region A1. The second transistor T2 may include a second semiconductor AS2 and the second gate electrode G2. The second semiconductor layer AS2 may include the second channel region A2, and the second source region S2 and the second drain region D2 on both sides of the second channel region A2.

The semiconductor layer AS may include the first channel region A1, the first source region Si, and the first drain region D1 which are the first semiconductor layer AS1 of the first transistor T1, and the second channel region A2, the second source region S2, and the second drain region D2 which the second semiconductor layer AS2 of the second transistor T2. For example, the channel region, the source region, and the drain region of each of the first transistor T1 and the second transistor T2 may be some or a number of portions of the semiconductor layer AS.

The semiconductor layer AS including the first semiconductor layer AS1 and the second semiconductor layer AS2 may have a curved shape, and the first channel region A1 and the second channel region A2 may be formed to be longer. For example, because the semiconductor [symbol] layer AS has a shape that is bent multiple times such as ‘⊂’, ‘ [symbol] ’, ‘S’, ‘M’, or ‘W’, a long channel may be formed in a narrow space. Because the first channel region A1 and the second channel region A2 are formed long, a driving range of a voltage of the first gate electrode G1 and the second gate electrode G2 may increase, a gray level of light emitted from the organic light-emitting diode OLED may be more precisely controlled, and display quality may be improved.

Although not shown, the first interlayer insulating layer 111 may be located on the semiconductor layer AS. The first interlayer insulating layer 111 may include an inorganic material including oxide or nitride. For example, the first interlayer insulating layer 111 may include at least one of silicon oxide (SiO₂), silicon nitride (SiNₓ), silicon oxynitride (SiOₓN_{y}), aluminum oxide (A1₂O₃), titanium oxide (TiO₂), tantalum oxide (Ta₂O₅), hafnium oxide (HfO₂), and zinc oxide (ZnO₂).

The first gate electrode G1, the second gate electrode G2, and the lower electrode CE1 of the first capacitor Cst1 may be located on the first interlayer insulating layer 111, as shown in FIG. 14B. The first gate electrode G1 may be a portion overlapping the first channel region A1 of the first semiconductor layer AS1. The second gate electrode G2 may be a portion overlapping the second channel region A2 of the second semiconductor layer AS2. The lower electrode CE1 of the first capacitor Cst1 may be integral with the first gate electrode G1.

Each of the first gate electrode G1, the second gate electrode G2, and the lower electrode CE1 of the first capacitor Cst1 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

Although not shown, the second interlayer insulating layer 112 may be located on the first gate electrode G1, the second gate electrode G2, and the lower electrode CE1 of the first capacitor Cst1. The initialization voltage line 121 and the upper electrode of the first capacitor may be located on the second interlayer insulating layer 112, as shown in FIG. 14C. The upper electrode of the first capacitor may overlap the lower electrode of the first capacitor. The upper electrode of the first capacitor and the initialization voltage line may be integral with each other.

Each of the initialization voltage line 121 and the upper electrode CE2 of the first capacitor Cst1 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

Although not shown, the third interlayer insulating layer 113 may be located on the initialization voltage line 121 and the upper electrode CE2 of the first capacitor Cst1. A third bridge metal layer 161, a fourth bridge metal layer 162, a fifth bridge metal layer 163, and the first scan line SL1 may be located on the third interlayer insulating layer 113, as shown in FIG. 14D.

The third bridge metal layer 161 may be electrically connected to the initialization voltage line 121 located under or below the third bridge metal layer 161 through a contact hole 81. Also, the third bridge metal layer 161 may be electrically connected to the second gate electrode G2 of the second transistor T2 through a contact hole 82. The initialization voltage line 121 and the second gate electrode G2 of the second transistor T2 may be electrically connected to each other, through the third bridge metal layer 161. In other words, the first scan line SL1 applied to the initialization voltage line 121 and the second gate electrode G2 of the second transistor T2 may be shared.

Because the first scan line SL1 connected to the initialization voltage line 121 and the second gate electrode G2 of the second transistor T2 is shared through the third bridge metal layer 161, pixel circuits may be more integrated in a display apparatus, thereby achieving ultra-high resolution. Also, because the initialization voltage line 121 and the first scan line SL1 are shared with each other, wirings of a pixel circuit may be further simplified. Due to the simplification of the pixel circuit, in a display apparatus that operates simultaneously for ultra-high resolution, leakage current generated in a transistor may be prevented, and a luminance difference due to an influence difference of leakage current between upper and lower transistors of the display apparatus may be prevented.

The fourth bridge metal layer 162 may be electrically connected to the first source region S1 of the first transistor T1 through a contact hole 71. The fifth bridge metal layer 163 may be electrically connected to the first drain region D1 of the first transistor T1 through a contact hole 72. Other bridge metal layers shown in FIG. 14D may be electrically connected to the second source region S2 and the second drain region D2 of the second transistor T2 through contact holes.

The first scan line SL1 may extend in the first direction (for example, the x direction or the −x direction). The first scan line SL may overlap at least a part of the third semiconductor layer A03 of the third transistor T3 located on the first scan line SL1. At least a part of the first scan line SL overlapping at least a part of the third semiconductor layer A03 of the third transistor T3 may function as a lower gate electrode of the third transistor T3.

Although not shown, the fourth interlayer insulating layer 114 may be located on the third to fifth bridge metal layers 161, 162, and 163 and the first scan line SL1. The oxide semiconductor layer AO including the third semiconductor layer A03 of the third transistor T3 may be located on the fourth interlayer insulating layer 114, as shown in FIG. 14E.

The oxide semiconductor layer AO may include a Zn oxide-based material such as Zn oxide, In—Zn oxide, or Ga—In—Zn oxide. In an embodiment, the semiconductor layer AO may include an In—Ga—Zn—O (IGZO), In—Sn—Zn—O (ITZO), or In—Ga—Sn—Zn—O (IGTZO) semiconductor containing a metal such as indium (In), gallium (Ga), or tin (Sn) in ZnO.

The third semiconductor layer A03 of the third transistor T3 may include a channel region, and a source region and a drain region on both sides of the channel region. The source region and the drain region of the third transistor T3 may be formed by adjusting a carrier concentration of an oxide semiconductor to make conductive. For example, the source region and the drain region of the third transistor T3 may be formed by increasing a carrier concentration through plasma treatment using a hydrogen (H)-based gas, a fluorine (F)-based gas, or a combination thereof on an oxide semiconductor.

Although not shown, the fifth interlayer insulating layer 115 may be located on the oxide semiconductor layer AO. The third gate electrode G3 may be located on the fifth interlayer insulating layer 115. The third gate electrode G3 may be a portion overlapping the third channel region A3 of the third transistor T3.

The third gate electrode G3 may have a single or multi-layer structure including at least one of aluminum (A1), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

According to the one or more embodiments, a display apparatus with improved quality and reliability may be realized. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope and as defined by the following claims.

What is claimed is:

1. A display apparatus comprising:
a display area including a display element;
a first thin-film transistor disposed in the display area, the first thin-film transistor comprising a first semiconductor layer and a first gate electrode insulated from the first semiconductor layer, the first semiconductor layer comprising a silicon semiconductor;
a second thin-film transistor disposed on the first thin-film transistor, the second thin-film transistor comprising a second semiconductor layer and a second gate electrode insulated from the second semiconductor layer, the second semiconductor layer comprising an oxide semiconductor;
a third thin-film transistor disposed on the first thin-film transistor, the third thin-film transistor comprising a third semiconductor layer and a third gate electrode insulated from the third semiconductor layer, the third semiconductor layer comprising an oxide semiconductor;
a bridge metal layer disposed between the first thin-film transistor and the second thin-film transistor and electrically connected to the first semiconductor layer through a first contact hole; and
a first conductive pattern layer disposed on the second gate electrode of the second thin-film transistor,
wherein the bridge metal layer is electrically connected to the first conductive pattern layer through a second contact hole.

2. The display apparatus of claim 1, wherein the second semiconductor layer comprises a first portion extending in a first direction and a second portion protruding from the first portion in a second direction intersecting the first direction.

3. The display apparatus of claim 2, wherein the second portion of the second semiconductor layer is disposed between the second gate electrode of the second thin-film transistor and the third gate electrode of the third thin-film transistor in a plan view.

4. The display apparatus of claim 1, wherein
the first semiconductor layer comprises a channel region, and a source region and a drain region disposed on both sides of the channel region, and
the bridge metal layer is electrically connected to the source region and the drain region of the first semiconductor layer through the first contact hole.

5. The display apparatus of claim 1, wherein
the second semiconductor layer and the third semiconductor layer are disposed on a same layer and comprise a same material, and
the second gate electrode and the third gate electrode are disposed on a same layer and comprise a same material.

6. The display apparatus of claim 1, wherein
the first thin-film transistor comprises a driving transistor, and
each of the second thin-film transistor and the third thin-film transistor comprises a switching transistor.

7. The display apparatus of claim 1, wherein the first conductive pattern layer comprises a driving voltage line.

8. The display apparatus of claim 1, further comprising:
a first scan line and a second scan line disposed below the second semiconductor layer to overlap at least a part of the second semiconductor layer, the first scan line and the second scan line extending in a first direction.

9. The display apparatus of claim 8, wherein the first scan line, the second scan line, and the bridge metal layer are disposed on a same layer and comprise a same material.

10. The display apparatus of claim 1, further comprising:
a first capacitor comprising a first lower electrode disposed on the first semiconductor layer and a first upper electrode disposed on the first lower electrode.

11. The display apparatus of claim 10, wherein the first lower electrode and the first gate electrode of the first thin-film transistor are integral with each other.

12. The display apparatus of claim 1, further comprising:
a second capacitor comprising a second lower electrode disposed on the second thin-film transistor and a second upper electrode disposed on the second lower electrode.

13. The display apparatus of claim 12, wherein the second lower electrode and at least a part of the first conductive pattern layer are integral with each other.

14. The display apparatus of claim 1, further comprising:
a second conductive pattern layer disposed on the first conductive pattern layer; and
a third conductive pattern layer disposed between the first conductive pattern layer and the second conductive pattern layer.

15. The display apparatus of claim 14, wherein the first conductive pattern layer is electrically connected to at least a part of the second conductive pattern layer through a third contact hole.

16. The display apparatus of claim 14, further comprising:
a third capacitor comprising a third lower electrode disposed on the second thin-film transistor, a third upper electrode disposed on the third lower electrode, and a third intermediate electrode disposed between the third upper electrode and the third lower electrode.

17. The display apparatus of claim 16, wherein
the third lower electrode is integral with at least a part of the first conductive pattern layer,
the third upper electrode is integral with at least a part of the second conductive pattern layer, and
the third intermediate electrode is integral with at least a part of the third conductive pattern layer.

18. A display apparatus comprising:
a display area including a display element;
a first thin-film transistor disposed in the display area, the first thin-film transistor comprising a first semiconductor layer and a first gate electrode insulated from the first semiconductor layer, the first semiconductor layer comprising a silicon semiconductor;
a second thin-film transistor disposed in the display area, the second thin-film transistor comprising a second semiconductor layer and a second gate electrode insulated from the second semiconductor layer, the second semiconductor layer comprising a silicon semiconductor;
a third thin-film transistor disposed on the first thin-film transistor, the third thin-film transistor comprising a third semiconductor layer and a third gate electrode insulated from the third semiconductor layer, the third semiconductor layer comprising an oxide semiconductor;
an initialization voltage line disposed on the first gate electrode and the second gate electrode; and
a bridge metal layer disposed between the initialization voltage line and the third thin-film transistor, the bridge metal layer being electrically connected to the initialization voltage line through a first contact hole,
wherein the bridge metal layer is electrically connected to the second gate electrode of the second thin-film transistor through a second contact hole.

19. The display apparatus of claim 18, wherein
the first semiconductor layer of the first thin-film transistor and the second semiconductor layer of the second thin-film transistor are disposed on a same layer and comprise a same material, and
the first gate electrode and the second gate electrode are disposed on a same layer and comprise a same material.

20. The display apparatus of claim 18, wherein
the first thin-film transistor comprises a driving transistor, and
each of the second thin-film transistor and the third thin-film transistor comprises a switching transistor.
